(19) United States
(12) Patent Application Publication
(10) Pub. No.: US 2025/0287547 A1
(43) Pub. Date: Sep. 11, 2025

(54) SPINE INTERCONNECT DEVICE FOR A DATACENTER

(71) Applicant: CGG Services SAS, Massy (FR)

(72) Inventors: Laurent Clerc, Houston, TX (US); Jean-Yves Blanc, Massy Cedex (FR); Robbie Case, Houston, TX (US)

(73) Assignee: CGG Services SAS, Massy (FR)

(21) Appl. No.: 18/598,496

(22) Filed: Mar. 7, 2024

(51) Int. Cl. H05K 7/20; H02G 5/02; H05K 7/14

(52) U.S. Cl. CPC H05K 7/20763; H02G 5/025; H05K 7/1485

(57) ABSTRACT

A spine interconnect device for a datacenter with liquid-cooled electronic components. The spine interconnect device includes a first bus bar and a second bus bar. The first and second bus bars each include one or more high power conductors. The spine interconnect device further includes a spine support configured to suspend the first bus bar and the second bus bar above the electronic components and a plurality of tap-off boxes each with a plurality of power ports. Each tap-off box is connected to and supported by the first bus bar or the second bus bar. The spine interconnect device further includes a plurality of power cables interconnecting the plurality of power ports to the electronic components, a low power tray with networking cables, and a networking switch. The spine interconnect device further includes a cold water conduit and a warm water return conduit and a manifold.

### BACKGROUND

In general, a datacenter includes a collection of computing resources such as servers, routers, network switches, and data storage housed within a facility. In operation, the computing resources of a datacenter consume power and generate heat. Further, the computing resources are interconnected through a power chain and data network, both of which typically employ the use of cables. As such, a datacenter is associated with one or more datacenter requirements related to, among others, power consumption and heat dissipation. That is, to operate a datacenter proper consideration to, at least, a network infrastructure, a power infrastructure, and a cooling infrastructure must be given according to the datacenter requirements. Often, the datacenter requirements are strongly tied to, or enacted by, the facility housing the computing resources; or, in other words, the facility considered as the datacenter. Consequently, changes in the computing resources of a datacenter, for example, adding additional computing resources, may directly affect the datacenter requirements of the datacenter requiring changes to the facility.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

Embodiments disclosed herein generally relate to a spine interconnect device for a datacenter with liquid-cooled electronic components. The spine interconnect device includes a bus bar support and a first bus bar suspended from the bus bar support, where the first bus bar includes one or more high power conductors of a plurality of high power conductors. The spine interconnect device further includes a second bus bar suspended from the bus bar support, where the second bus bar includes one or more high power conductors of the plurality of high power conductors. The spine interconnect device further includes a spine support configured to suspend the bus bar support, the first bus bar, and the second bus bar above the electronic components and a plurality of tap-off boxes each comprising a plurality of power ports, where each tap-off box of the plurality of tap-off boxes is connected to and supported by the first bus bar or the second bus bar. Additionally, each of the plurality of tap-off boxes connects to one or more of the high power conductors. The spine interconnect device further includes a plurality of power cables interconnecting the plurality of power ports to the electronic components, a low power tray supported by the spine support disposed below the first bus bar and the second bus bar and above the electronic components where the low power tray carries networking cables connected to one or more of the electronic components, and a networking switch at a terminal end of the spine interconnect device. The spine interconnect device further includes a cold water conduit and a warm water return conduit disposed at a base of the spine support and a manifold fluidly connecting the cold water conduit and the warm water return conduit to an environment for cooing the liquid-cooled electronic components.

Embodiments disclosed herein generally relate to a method for using a spine interconnect device in a datacenter with liquid-cooled electronic components. The method includes providing the spine interconnect device in the datacenter, where the spine interconnect device includes a first bus bar with a first set of one or more high power conductors. The spine interconnect device further includes a first spine support configured to suspend the first bus bar above the electronic components and a first plurality of tap-off boxes each with a plurality of power ports, where each tap-off box of the first plurality of tap-off boxes is connected to and supported by the first bus bar and connects to one or more of the high power conductors in the first set. The spine interconnect device further includes a plurality of power cables interconnecting the plurality of power ports to the electronic components and a cold water conduit and a warm water return conduit disposed at a base of the spine support. The spine interconnect device further includes a manifold fluidly connecting the cold water conduit and the warm water return conduit to the liquid-cooled electronic components. The method further includes connecting the first set of one or more high power conductors to a first main power source and connecting the cold water conduit and the warm water return conduit to a cooling system including a pump and an external heat exchanger. The method further includes pumping water through the cold water conduit to the liquid-cooled electronic components and extracting heat generated by the electronic components to the water and pumping the heated water to the external heat exchanger.

Embodiments disclosed herein generally relate to a datacenter including a cooling fluid immersion environment of electronic components and a first spine interconnect device. The first spine interconnect device includes a first bus bar support and a first bus bar suspended from the first bus bar support, where the first bus bar includes one or more high power conductors of a first plurality of high power conductors. The first spine interconnect device further includes a second bus bar suspended from the first bus bar support, where the second bus bar includes one or more high power conductors of the first plurality of high power conductors. The first spine interconnect device further includes a first spine support configured to suspend the first bus bar support, the first bus bar, and the second bus bar above the electronic components. The first spine interconnect device further includes a first plurality of tap-off boxes each with a plurality of power ports, where each tap-off box of the first plurality of tap-off boxes is connected to and supported by the first bus bar or the second bus bar. Additionally, each of the first plurality of tap-off boxes connects to one or more of the high power conductors of the first plurality of high power conductors. The first spine interconnect device further includes a first plurality of power cables interconnecting the plurality of power ports to the electronic components, a first low power tray supported by the first spine support disposed below the first bus bar and the second bus bar and above the electronic components where the first low power tray carries networking cables connected to one or more of the electronic components, and a first networking switch at a terminal end of the first spine interconnect device. The first spine interconnect device further includes a first cold water conduit and a first warm water return conduit disposed at a base of the first spine support and a first manifold fluidly connecting the first cold water conduit and the first warm water return conduit to the cooling fluid immersion environment. In one or more embodiments, the datacenter further includes a second spine interconnect device that includes a second bus bar support and a third bus bar suspended from the second bus bar support, where the third bus bar includes one or more high power conductors of a second plurality of high power conductors. The second spine interconnect device further includes a fourth bus bar suspended from the second bus bar support, the fourth bus bar including one or more high power conductors of the second plurality of high power conductors. The second spine interconnect device further includes a second spine support configured to suspend the second bus bar support, the third bus bar, and the fourth bus bar above the electronic components and a second plurality of tap-off boxes each with a plurality of power ports, where each tap-off box of the second plurality of tap-off boxes is connected to and supported by the third bus bar or the fourth bus bar. Additionally, each of the second plurality of tap-off boxes connects to one or more of the high power conductors of the second plurality of high power conductors. The second spine interconnect device further includes a second plurality of power cables interconnecting the plurality of power ports to the electronic components, a second low power tray supported by the second spine support disposed below the third bus bar and the fourth bus bar and above the electronic components, where the second low power tray carries networking cables connected to one or more of the electronic components, and a second networking switch at a terminal end of the second spine interconnect device. The second spine interconnect device further includes a second cold water conduit and a second warm water return conduit disposed at a base of the second spine support and a second manifold fluidly connecting the second cold water conduit and the second warm water return conduit to the cooling fluid immersion environment.

Any combinations of the various embodiments and implementations disclosed herein can be used in a further embodiment, consistent with the disclosure. Other aspects and advantages of the claimed subject matter will be apparent from the following description and the claims.

### BRIEF DESCRIPTION OF DRAWINGS

Specific embodiments of the disclosed technology will now be described in detail with reference to the accompanying figures. Like elements in the various figures are denoted by like reference numerals for consistency. The sizes and relative positions of elements in the drawings are not necessarily drawn to scale. For example, the shapes of various elements and angles are not necessarily drawn to scale, and some of these elements may be arbitrarily enlarged and positioned to improve drawing legibility.

FIG. 1 depicts a block diagram of a datacenter in accordance with one or more embodiments.

FIG. 2 depicts a spine interconnect device in accordance with one or more embodiments.

FIG. 3 depicts a spine support in accordance with one or more embodiments.

FIG. 4 depicts a datacenter employing a spine interconnect device in accordance with one or more embodiments.

FIG. 5 depicts a method for using a spine interconnect device in a datacenter in accordance with one or more embodiments disclosed herein.

### DETAILED DESCRIPTION

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers is not intended to imply or create any particular ordering of the elements nor to limit any element to being only a single element unless expressly disclosed, such as using the terms “before,” “after,” “single,” and other such terminology. Rather, the use of ordinal numbers is to distinguish between the elements. By way of an example, a first element is distinct from a second element, and the first element may encompass more than one element and succeed (or precede) the second element in an ordering of elements. Furthermore, while certain components are referred to in the singular to simplify discussion of embodiments of the invention, those skilled in the art will appreciate that any individual component (i.e., an electronic component) may be replaced with a multitude of components in advanced embodiments of the invention.

In addition, throughout the application, the terms “upper” and “lower” may be used to describe the position of an element of the invention. In this respect, the term “upper” denotes an element disposed above a corresponding “lower” element in a vertical direction, while the term “lower” conversely describes an element disposed below a corresponding “upper” element in the vertical direction.

In one aspect, embodiments disclosed herein relate to a spine interconnect device that provides all necessary physical connectivity to the computing resources and other components of a datacenter. In general, physical connectivity includes a network infrastructure, a power infrastructure, and a cooling infrastructure to provide communication between devices of the datacenter both within the datacenter and external to the datacenter, to supply power to the computing resources, and to dissipate heat generated by components of the datacenter, respectively. Because the spine interconnect device provides all necessary physical connectivity to the components of a datacenter, including a cooling infrastructure to remove heat generated by the components of the datacenter, datacenter requirements can be met without significant consideration for the facility associated with, or otherwise housing, the datacenter. That is, among other benefits discussed later in the instant disclosure, the spine interconnect device removes datacenter requirements from facility considerations and greatly expands the number and type of facilities that can be used as a datacenter. For example, and as will be demonstrated herein, the spine interconnect device can be installed in a basic facility (e.g., a facility providing only shelter from an external environment, or a conventional container) or can be used to retrofit or expand existing datacenters with minimal (if any) disruption to the operation of the datacenter and with relatively low cost (i.e., without alteration of the facility itself).

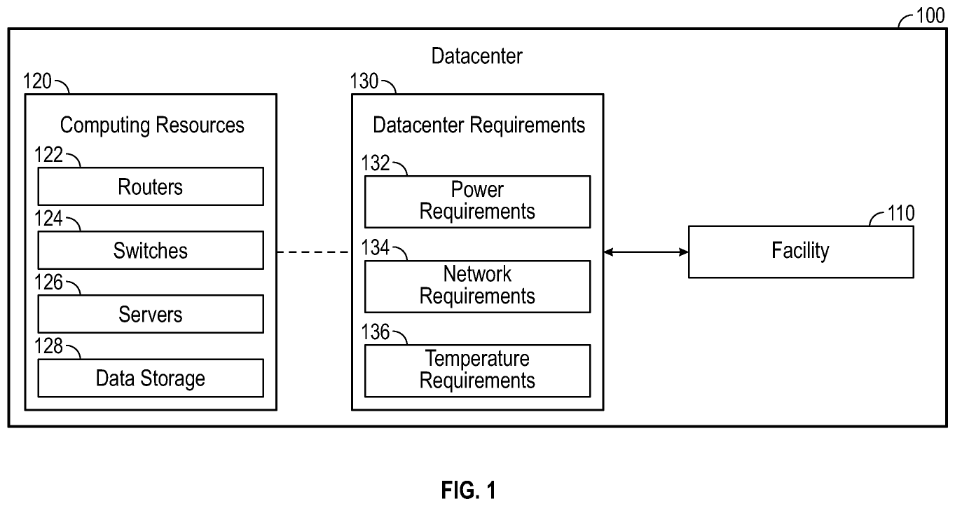

FIG. 1 depicts a block diagram of an example datacenter (100), in accordance with one or more embodiments. In FIG. 1, the datacenter (100) is depicted as consisting of various blocks representative of both concrete items and abstract concepts, where the blocks may interact with, or otherwise inform, one another. One with ordinary skill in the art will recognize that the partitioning, organization, and interaction of the blocks of the datacenter (100) depicted in FIG. 1 is intended to promote clear discussion and should not be considered fixed or limiting. That is, a block diagram representative of a datacenter can be structured and illustrated in many different ways and embodiments of the present disclosure are not reliant on a datacenter as depicted in FIG. 1. Further, FIG. 1 depicts a facility (110) as element of the datacenter (100), however, it is well understood that in practice references to a datacenter may refer to a facility, or, more specifically, a facility configured as a datacenter.

In general, a datacenter (100) includes, or is, a facility (110) that hosts computing resources (120) and other auxiliary devices or infrastructure systems, where the collection of computing resources (120) and associated devices and/or systems are used to store, process, and distribute large amounts of data. As depicted in FIG. 1, the computing resources of a datacenter (100) can include, but are not limited to, routers (122), switches (124), servers (126), and data storage (128) systems. Computing resources (120) of a datacenter (100) may further include firewalls and application delivery controllers. In some implementations, the computing resources (120) of a datacenter (100), and additional information concerning their quantity, operation, and configuration, define a set of datacenter requirements (130) that should be met to operate the datacenter (100). For example, computing resources (120) consume power and dissipate heat. As such, to operate a datacenter (100) the datacenter (100) should be equipped with or otherwise connected to a power supply and cooling system sufficient to provide power to and cool the computing resources (120), respectively, as defined by the datacenter requirements (130).

FIG. 1 depicts three categorizations for datacenter requirements (130), namely, power requirements (132), network requirements (134), and temperature requirements (136). It is noted that additional categorizations for datacenter requirements (130), other than those depicted in FIG. 1, can exist and do not exceed the scope of this disclosure. For example, in some implementations, datacenter requirements (130) may further be categorized as a storage requirement. In summary, a given datacenter (100) requires a specified amount of power for its computing resources (120), connectivity devices (e.g., cables) to connect said computing resources (120) both within the datacenter (100) and to external systems, and a method or system to maintain the computing resources (120) at a specified temperature (or below a specified temperature or within a range of operating temperatures).

In one or more implementations, devices and elements of a datacenter (100) can also be classified according to a type of infrastructure. For example, connectivity devices (e.g., cables) of a datacenter (100) may be included in a so-called “network infrastructure” of the datacenter (100). Similarly, a power source, power subsystems, power supply cables, uninterruptible power supplies (UPS), and other devices, may be included in a so-called “power infrastructure” of the datacenter (100). As another example, heat transfer devices, ventilation systems, and cooling systems may be included in a so-called “cooling infrastructure” of the datacenter (100). In some implementations, there is an inherent relationship between the categorizations of datacenter requirements (130) and the infrastructure systems (or classes of infrastructure) included in, or associated with, the datacenter (100). For example, the power infrastructure of the datacenter (100) includes all devices and elements required to meet the power requirements (132) in accordance with the demands of the computing resources (120). Similarly, the cooling infrastructure includes all devices and elements used to cool, or otherwise meet the temperature requirements (136), of the computing resources (120). As another example, the network infrastructure includes all connections between servers (126) (both physical and virtualized), data storage (128), and external connectivity to end-user locations.

Conventionally, datacenter requirements (130) are met using the facility (110) housing the computing resources (120), or the facility (110) configured as a datacenter (100). That is, conventionally, power infrastructure, network infrastructure, and cooling infrastructure are provided by, or strongly tied to, the facility (110). As an example, a facility (110) may be equipped with a cooling infrastructure including one or more Computer Room Air Conditioning (CRAC) units and Computer Room Air Handler (CRAH) units to maintain the temperature of the facility at a specified temperature according to the temperature requirements (136).

The facility (110) may also provide physical security in the form alarms, biometric scanners, and electronic door locks to protect its enclosed assets.

As discussed, power infrastructure, network infrastructure, and cooling infrastructure, among other things, needed to operate a datacenter (100) according to its datacenter requirements (130) are often provided by, or strictly tied to, the facility (110) of the datacenter (100). Consequently, changes in the computing resources (120) of a datacenter (100), for example, adding additional computing resources (i.e., “scaling up” a datacenter), may directly affect the datacenter requirements (130) and necessitate, or otherwise be associated with, changes to the facility. For example, in instances where cooling infrastructure is provided to maintain an ambient temperature in a facility as a whole (e.g., CRAC, CRAH), the entire facility must be completed before a datacenter can become operational, including the environmental control of portions of the facility that do not directly house computing resources. In some instances, the use of CRAC units and CRAH units to cool a facility are avoided, in part, because their cooling or heat dissipation effect generally cannot be localized or directed to specific computing resources (120) or regions of the facility (110). Further, the use of CRAC units as the cooling infrastructure of a datacenter (100) may be inefficient due to the low heat capacity of air relative to other coolants such as water. In some instances, the cooling infrastructure of a datacenter (100) may include a form of liquid cooling where a cooling liquid such as water is pumped to heat exchangers or coils disposed in closer proximity to the computing resources (120). However, conventionally, cooling infrastructures involving directed liquid cooling are still tied to the facility (110), as a cooling grid including at least a supply conduit and a return conduit for the cooling fluid are typically suspended from the ceiling of the facility (110) or disposed in a subfloor of the facility (110).

As will be demonstrated, the spine interconnect device as described herein provides power infrastructure, network infrastructure, and cooling infrastructure to a datacenter (100) that uses one or more liquid-cooled computing resources (120) (e.g., servers (126)) without affecting or necessitating alterations of the facility (110). As such, the spine interconnect device promotes, among other things, modularity and cost-efficient scaling of a datacenter.

While some datacenter systems may claim enhanced or improved modularity, these alleged modular datacenter systems generally employ methods and systems to operate a datacenter in a partially completed facility. That is, a portion of a facility may be made available for operation of computing resources and, in response to an increase in demand, additional portions of the facility can be made operational to expand the computing system without interrupting the previously installed computing resources, or the like. While these so-called modular systems may be considered advantageous over conventional datacenter systems that require a fully complete facility (e.g., a fully and commonly environmentally controlled facility), they still require incremental facility update and expansion efforts. In contrast, another benefit of the spine interconnect device is that it allows for a near complete decoupling of facility and datacenter requirement interaction. In a most minimal sense, the facility of a datacenter employing the spine interconnect device need only provide shelter of the computing resources and other components of the data center from external environmental factors such as rain and dust.

Often, datacenters are further classified according to a principal function, provided service, computational speed, and/or data storage size. For example, a datacenter may be classified as a hyperscale datacenter, a cloud data center, or an edge data center. Further, classes of datacenters need not be mutually exclusive. A hyperscale datacenter may be used to support large-scale information technology projects capable of supporting thousands of individual servers. In contrast, an edge datacenter may be configured to reduce latency to support emergency applications and real-time automation systems. Embodiments disclosed herein are applicable to any class of datacenter so long as the datacenter employs at least some liquid-cooled computing resources. Further, while embodiments disclosed herein are described in the context of a datacenter employing liquid-cooled computing resources, embodiments of the disclosure are not limited strictly to datacenters. In general, the spine interconnect device can be used in any situation where a collection of computing resources is operated in conjunction with a power infrastructure, network infrastructure, and cooling infrastructure (or, more generally, operated according to some power requirements (132), network requirements (134), and temperature requirements (136)). For example, a High Performance Computing (HPC) system can include a collection of computing resources and associated components. In situations where one or more computing resources of the HPC system (and other components) are liquid-cooled, the spine interconnect device described herein is readily applicable to such a system. In some instances, an HPC system may be considered a class of datacenter. As such, while the instant disclosure may adopt the use of the term datacenter, it is emphasized that embodiments of the instant disclosure are not limited to this choice of nomenclature. In general, and as will be demonstrated, the spine interconnect device is applicable to a collection of liquid-cooled computing resources, or other like or associated components, with associated power, network, and temperature (or cooling) requirements.

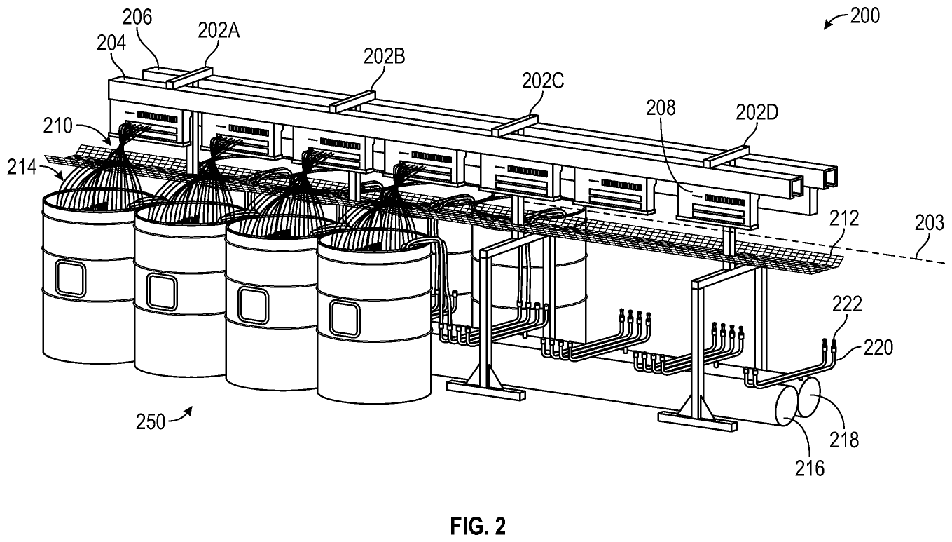

FIG. 2 depicts a spine interconnect device (200) in partial use with a collection of liquid-cooled electronic components (e.g., servers (126)). The term “partial” refers to the fact that there is portion of the spine interconnect device (200) in FIG. 2 that is not connected to liquid-cooled components. In practice, the spine interconnect device (200) can be fully connected to liquid-cooled components, where the partial view of FIG. 2 is given to provide an unobstructed view of components of the spine interconnect device (200).

In the example of FIG. 2, the liquid-cooled electronic components are disposed in a set of barrels, the barrels being filled with a first cooling fluid such as mineral oil (e.g., a dielectric oil). A datacenter where the computing resources (120), or at least some of the computing resources such as those that produce a significant amount of heat such as servers (126), are immersed in a liquid for cooling may be said to employ cooling fluid immersion (250) (also described as a cooling fluid immersion system or a cooling fluid immersion environment). In one or more implementations, the first cooling fluid in which one or more of the computing resources (e.g., servers (126)) are immersed is mineral oil.

The use of mineral oil as a first cooling fluid for cooling fluid immersion (250) is advantageous because mineral oil is nontoxic, inexpensive, easy to handle, does not conduct electricity, and can dissipate large amounts of heat compared to a cooling infrastructure that uses air cooling (e.g., CRAC units). For example, some estimates indicate that cooling fluid immersion can dissipate heat at a density at, or greater than, 4 kW/1 U (or approximately equivalent to 150 KW per rack). In contrast, fundamental physical principles and practical considerations regarding the rate of air flow, the temperature differential between air and heat-generating computational resources, and the corresponding heat transfer coefficient limit the maximum heat dissipation density of air cooling systems to 30-35 kW/rack.

In a cooling fluid immersion system (250), heat is extracted from the first cooling fluid in which the liquid-cooled electronic components are immersed. In one or more embodiments, a cooling loop including, at least, a supply and a return conduit, a second cooling fluid, and a pump, is used to extract heat from the cooling fluid immersion system (250) (e.g., from the first cooling fluid) by transferring heat from the first cooling fluid to the second cooling fluid using, for example a heat exchanger formed within, around, or in close proximity to the first cooling fluid (e.g., a heat exchanger disposed circumferentially within a barrel). The supply conduit of the cooling loop supplies the second cooling fluid at a relatively cool temperature. The relatively cool second cooling fluid increases in temperature as heat is transferred to it from the first cooling fluid and is conveyed from the cooling fluid immersion system (250) at a relatively elevated temperature by the return conduit. The return conduit, in turn, connects to an external heat exchanger or cooling plant that can be located outside the facility (110), or, at least outside the portion of the facility (110) that houses the computing resources (120). In one or more embodiments, the external heat exchanger or cooling plant supplies the relatively cool second cooling fluid to the supply conduit upon removing heat from the second cooling fluid (e.g., through exchange with an external environment). In one or more embodiments, a heat exchanger is not used between the first cooling fluid and the second cooling fluid, rather the first cooling fluid is directly circulated through the cooling loop.

While FIG. 2 depicts the liquid-cooled electronic components as being immersed in a first cooling fluid as part of a fluid cooling immersion system or environment (250), it is noted that the reference to “liquid-cooled” electronic components refers to the cooling (or extraction of heat) from the liquid-cooled electronic components using a cooling loop. That is, liquid-cooled electronic components need not be immersed in a first cooling fluid or otherwise be considered part of a fluid cooling immersion system or environment (250). For example, in one or more implementations, a cooling loop can be used to circulate a second cooling fluid through a heat exchanger or coil proximate to an electronic component (e.g., server (126)) without the electronic component being immersed in a first cooling fluid. In such a case, the electronic component would still be considered to be “liquid-cooled.” In summary, the spine interconnect device (200) can be used in, or used to construct, any datacenter (100) that uses a cooling loop, where, in such a case, one or more computing resources (120) are considered as liquid-cooled electronic components. Further, while the cooling fluid immersion system or environment (250) depicted in FIG. 2 makes use of barrels to hold the first cooling fluid and the liquid-cooled electronic components, the spine interconnect device (200) used with a cooling fluid immersion environment (250) is not limited to use with these barrels. In some instances, a heterogeneous combination of containers may be used in a cooling fluid immersion environment (250) to hold the first cooling fluid. Additionally, in one or more embodiments using a cooling fluid immersion system (250), the first cooling fluid and the second cooling fluid may be the same.

Continuing with FIG. 2, the spine interconnect device (200) includes one or more spine supports. Specifically, FIG. 2 depicts a first spine support (202A), a second spine support (202B), a third spine support (202C), and a fourth spine support (202D). For simplicity, without need to reference a specific spine support (202A, 202B, 202C, 202D) the collection of one or more spine supports of the spine interconnect device (200) will be referred to as spine supports (202). In instances where the spine interconnect device (200) includes more than one spine support (202), the spine supports (202) are separated by a separation distance. In one or more embodiments, three or more spine supports (202) are separated from their adjacent spine supports (202) by an equal separation distance such that spine supports (202) are equally spaced and equidistant from one another. In one or more embodiments, the separation distance between each spine support (202) is 1.5 m. In some embodiments, the separation distance is not equal between pairs of adjacent spine supports (202). As will be described below, in one or more embodiments, a spine support (202) defines, or is associated with, a frontal plane (i.e., the plane on which the spine support is projected when viewed from the “front”). A spine axis (203) extends through each spine support (202) in a series of spine supports (202) and is locally orthogonal to the frontal plane of each spine support (202). The spine axis (203) can be substantially straight as depicted in FIG. 2 or curved according to the relative positioning and orientations of the spine supports (202) of the spine interconnect device (200).

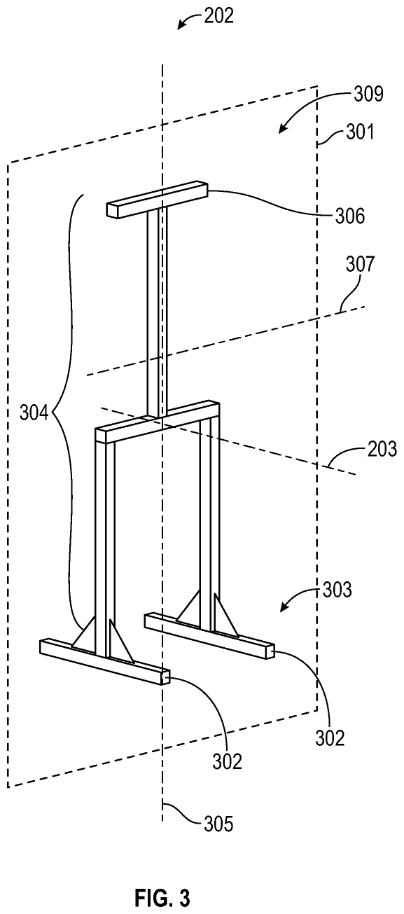

FIG. 3 depicts a perspective view of a spine support (202) in accordance with one or more embodiments. The spine support (202) has a lower portion (303) and an upper portion (309) with a vertical axis (305) orthogonal to a floor on which the spine support (202) is placed and extending between the lower portion (303) and the upper portion (309). Additionally, the spine support (202) defines, or can otherwise be described by, a transverse axis (307) parallel to the floor and parallel to a “width” or transverse extent of the spine support (202). The vertical axis (305) and transverse axis (307) are coplanar with a frontal plane (301) of the spine support (202). As discussed above, a spine axis (203) is orthogonal to the frontal plane (301) of the spine support (202). In accordance with one or more embodiments, the spine support (202) includes one or more floor supports (302). The one or more floor supports (302) contact the floor of the facility (110) that uses the spine interconnect device (200). In one or more embodiments, the one or more floor supports (302) may include a mounting bracket and/or bolt holes that can be used to mount, or otherwise affix, the spine support (202) to the floor. In accordance with one or more embodiments, the spine support (202) further includes an elevation portion (304) composed of one or more members that extend between the one or more floor supports (302) and a bus bar support (306). In one or more embodiments, the members of the elevation portion (304) are adjustable in length such that adjustment of the overall height of the support spine (202) is effectuated by adjusting the length of members of the elevation portion (304). For example, in instances where two or more spine supports (202) are used in a spine interconnect device (200) and the floor of the facility (110) in which the spine interconnect device (200) is not level (e.g., one or more steps in the facility), the elevation portion (304) of one or more of the spine supports (202) can be adjusted to maintain the upper portions (309) or bus bar supports (306) of the spine supports (202) at the same height with respect to a given absolute or global reference frame.

In other embodiments, the spine supports (202) are adapted to be suspended from a ceiling of the facility (110), or a gantry or mezzanine installed in the facility (110). In such a case, upper portion (309) (e.g., bus bar support (306)) includes a mounting bracket and/or bolt holes to mount, attach, or otherwise affix the spine support (202) to the ceiling, gantry, or mezzanine. The portion of the spine supports (202) that contacts the ceiling, gantry, mezzanine, or the like, can be referred to as a ceiling support. Further, the lower portion (303) may no longer include floor supports (302) but rather include a mechanical connection, such as a hinged split ring, to support, at least, a supply conduit and return conduit described below. Similar to a spine support (202) disposed on or mounted to the floor of the facility (110), suspended spine supports (202) (e.g., suspended from a ceiling, gantry, or mezzanine) provide structure for the spine interconnect device where the spine interconnect device provides power infrastructure, networking infrastructure, and cooling infrastructure to a datacenter (100).

Returning to FIG. 2, and in accordance with one or more embodiments, the spine interconnect device (200) includes two bus bars, namely, a first bus bar (204) and a second bus bar (206). The first bus bar (204) and the second bus bar (206) are each suspended from the bus bar support (306) of the one or more spine supports (202). The first bus bar (204) and the second bus bar (206) each convey or include one or more high power conductors (e.g., copper bars or tracks). Further, the first bus bar (204) and the second bus bar (206) are each configured to support one or more tap-off boxes (208). It is noted that to avoid cluttering FIG. 2 with numeric labels, only one tap-off box is labelled. Each of the one or more tap-off boxes (208) connects to one or more of the high power conductors conveyed and retained by the bus bars (204, 206). In accordance with one or more embodiments each tap-off box (208) includes a plurality of power ports, the power ports receiving power from the respective one or more high power conductors of the associated bus bar (204, 206). Power cables (210) are connected to the plurality of power ports to supply power to the liquid-cooled electronic components. Note that not all power cables (210) are labelled in FIG. 2. In other words, the bus bars (204, 206) contain high power conductors installed so that any number of tap-off boxes (208) can be safely inserted and connected anywhere along the associated bus bar (204, 206). In accordance with one or more embodiments, a connection box (not shown) is installed on a terminal end of each of the bus bars (204, 206). The connection box is connected by high power cables to a circuit powering the facility (110). The tap-off boxes (208) are connected to the electronic equipment (e.g., computing resources (120)) with requisite cabling as defined by the electronic equipment, the cabling typically operating at a lower amperage relative to the high power cables.

In accordance with one or more embodiments, the spine interconnect device (200) includes a low power tray (212) that supports various cables, such as network cables (214), between the liquid-cooled electronic components and associated terminals (e.g., network switch). In one or more embodiments, a networking switch is disposed at a terminal end of the spine interconnect device (200) and the low power tray (212) supports networking cables (214) connected to one or more of the liquid-cooled electronic components and the networking switch.

In accordance with one or more embodiments, the spine interconnect device (200) is connected to a cooling loop, as previously described, and includes the supply conduit (216) and the return conduit (218). In one or more embodiments, the second cooling fluid, or the cooling fluid used in the cooling loop, is water or a water-based mixture such as a mixture of water and ethylene glycol. In such instances, the supply conduit (216) and the return conduit (218) may be referred to as a cold water conduit (216) and a warm water return conduit (218), respectively, without undue ambiguity. As depicted in FIG. 2, in one or more embodiments, the cold water conduit (216) and the warm water return conduit (218) run parallel to the spine axis (203) of the spine interconnect device (200) and are disposed near the lower portion (303) of the spine supports (202).

The spine interconnect device (200) further includes at least one manifold (220) fluidly connected to the cold water conduit (216) and the warm water return conduit (218). Each of the manifolds (220) includes one or more second cooling fluid taps (222), e.g., spigots, each having a valve and an outlet that is configured for fastening a hose or pipe. In one or more embodiments, the outlet is threaded or otherwise configured with a connection compatible with a quick-connect (or quick-disconnect) fitting. Thus, the manifolds (220) can be used to fluidly connect the cold water conduit (216) and the warm water return conduit (218) to the device (e.g., coil, heat exchanger, etc.) or system (e.g., cooling fluid immersion environment) used to extract heat from the liquid-cooled electronic components. In one or more embodiments, the manifolds (220) have a regular spacing with respect to the spine axis (203). In some embodiments, the manifolds (220) have irregular spacing along the spine axis (203). In one or more embodiments, regardless of the spacing of the manifolds (220), the taps (e.g., spigots) associated with the cold water conduit (216) and the warm water return conduit (218) are provided at different intervals. For example, manifolds (220) with only a fluid connection to the cold water conduit (216) can be provided according to a first interval and manifolds (220) with only a fluid connection to the warm water return conduit (218) can be provided according to a second interval, where the first interval and the second interval need not be the same and may be offset according to a given offset distance. The flow capacity of the cold water conduit (216), warm water return conduit (218), and the manifolds (220) can be selected to meet or exceed the expected datacenter requirements (130).

In general, the configuration of the spine interconnect device (200) need not be as depicted in FIG. 2. For example, the cold water conduit (216) and the warm water return conduit (218) can be put on top of each other instead of side by side. Similarly, the first bus bar (204) and the second bus bar (206) can be placed or supported on top of one another, suspended from the bus bar support (308), disposed on top of the bus bar support (308), etc. Additionally, the low power tray (212) can be relocated. However, in general, the first bus bar (204) and the second bus bar (206) are stated to always be above the cold water conduit (216) and the warm water return conduit (218), and separated by enough distance to respect any applicable standard (e.g., country-specific safety standard). In one or more embodiments, the height of the spine supports (202) are adjusted to maintain a specified distance between the bus bars (204, 206) and the water conduits (216, 216) (and/or the at least one manifolds (220) and cooling fluid immersion environment (250), when applicable) according to a given standard. In one or more embodiments, additional monitoring equipment (power, pressure, temperature, leakage) and automatic controls (e.g., electric valves) can be disposed on the spine interconnect device (200) with any associated cabling running on the low power tray (212).

While not depicted in FIG. 2, it is noted that on a terminal end of the spine interconnect device (200), there is a connection box to a main power source (i.e., a circuit powering the facility) that supplies power to the high power conductors (i.e., the bus bars) and a connection to a cooling system (e.g., external heat exchanger or cooing plant) that receives the warm second cooling fluid from the return conduit (218), cools the second cooling fluid, and re-supplies the second cooling fluid to the supply conduit (216). Further, and as discussed above, on a terminal end of the spine interconnect device (200) there is a network connectivity device or network switch that connects cables supported by the low power tray (212) to external systems. In accordance with one or more embodiments, a terminal end of the spine interconnect device (200) is connected to two or more independent main power sources. In such a case, the first bus bar (204) and the second bus bar (206) can each connect to a different main power source to provide a level of redundancy to the power infrastructure of the datacenter (100). For example, the power cables (210) can be arranged such that the liquid-cooled electronic components can receive power from either the first bus bar (204) or the second bus bar (206) such that if the main power source corresponding to either the first bus bar (204) or the second bus bar (206) is interrupted, inactive, or nonfunctional, power can still be supplied to the liquid-cooled electronic components. In some embodiments, the first bus bar (204) and the second bus bar (206) supply power from a single main power source to provide the maximum available power to the datacenter (100), but without redundancy in the event of a power failure or interruption.

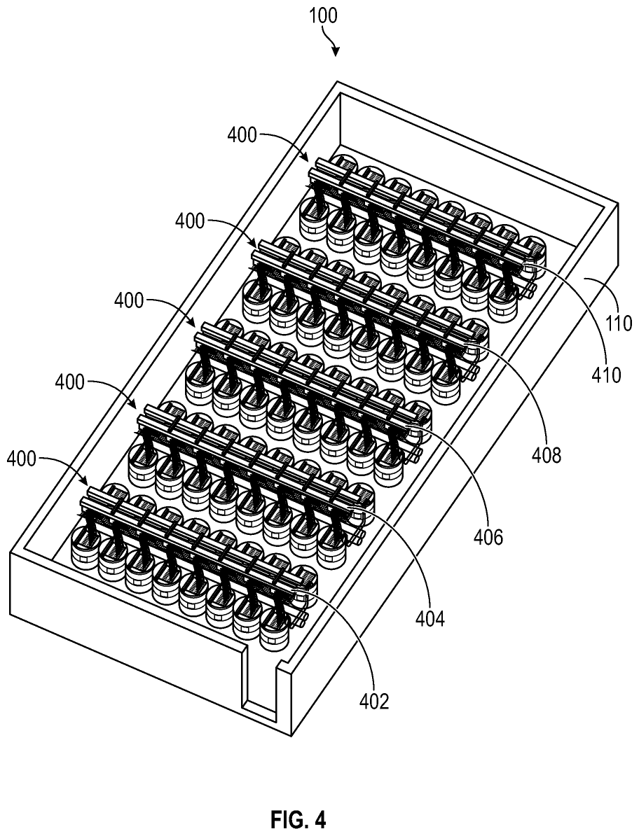

FIG. 4 depicts a datacenter (100) employing cooling fluid immersion that uses a plurality of spine interconnect devices (400) to provide power infrastructure, network infrastructure, and cooling infrastructure to multiple rows of liquid-cooled electronic components. In particular, FIG. 4 depicts a facility (110) used as a datacenter (100), the facility (110) organized with five rows, namely, a first row (402), a second row (404), a third row (406), a fourth row (408), and a fifth row (410) of liquid-cooled electronic components. Moreover, the liquid-cooled electronic components are immersed in a first cooling fluid contained in sets of barrels forming a cooling fluid immersion environment (250). As depicted, the power infrastructure, network infrastructure, and cooling infrastructure for each row (402, 404, 406, 408, 410) of liquid-cooled electronic components in the facility (110) is provided using an associated spine interconnect device (200), one for each row.

In one or more embodiments, the terminal ends of each of the spine interconnect devices of the plurality of spine interconnect devices (400) are connected to at least one of the same main power source or the same cooling system. In other embodiments, one or more of the spine interconnect devices of the plurality of spine interconnect devices (400) is connected to its own, independent main power source and/or cooling system.

In the depiction of FIG. 4, the spine interconnect devices extend down the centers of their respective rows with liquid-cooled electronic components on either side. In practice, the spine interconnect devices need not be configured as depicted in FIG. 4. For example, in one or more embodiments one or more spine interconnect devices are disposed about the interior perimeter of a facility (110) with liquid-cooled electronic components disposed only on one side of the spine interconnect devices. Further, it is again emphasized that a spine interconnect device (200), as described herein, can be used with any datacenter (100) with liquid-cooled electronic components and need not be associated with a cooling fluid immersion environment (250). For example, a datacenter (100) may house liquid-cooled electronic components in one or more racks equipped with a coil or heat exchanger and fan. In these cases, heat generated by the electronic components (or, more generally, the computing resources (120)) can be transferred to the second cooling fluid or liquid cooling system, where the second cooling fluid is conveyed to and from the racks by the supply conduit (216) and return conduit (218), respectively, of the spine interconnect device (200).

In accordance with one or more embodiments, the spine interconnect device (200) provides all necessary physical connectivity to the computing resources (120) and other components of a datacenter (100). In particular, the spine interconnect device (200) may be said to provide a network infrastructure, a power infrastructure, and a cooling infrastructure. Because the spine interconnect device (200) provides all necessary physical connectivity to the components of a datacenter (100), including a cooling infrastructure to remove heat generated by the liquid-cooled electronic components of the datacenter (100), datacenter requirements (130) can be met without significant consideration for the facility (110) associated with, or otherwise housing, the datacenter (100). That is, the spine interconnect device (200) removes datacenter requirements from facility architectural considerations and greatly expands the number and type of facilities that can be used as a datacenter (100). In fact, although the depiction of the datacenter (100) in FIG. 4 is simplified, the depicted facility (110) may be little more than a shelter that defines an interior space for the computing resources (120) of the datacenter (100). Thus, the spine interconnect device (200) can be installed in a basic facility (e.g., a facility providing only shelter from an external environment such as a warehouse) or can be used to retrofit or expand existing datacenters with minimal (if any) disruption to the operation of the datacenter and with relatively low cost (i.e., without alteration of the facility itself). The decoupling of datacenter requirements (130) from the facility (110) expands the options of facilities (110) that can be used or configured as datacenters (100) reducing a major cost factor of a datacenter (100).

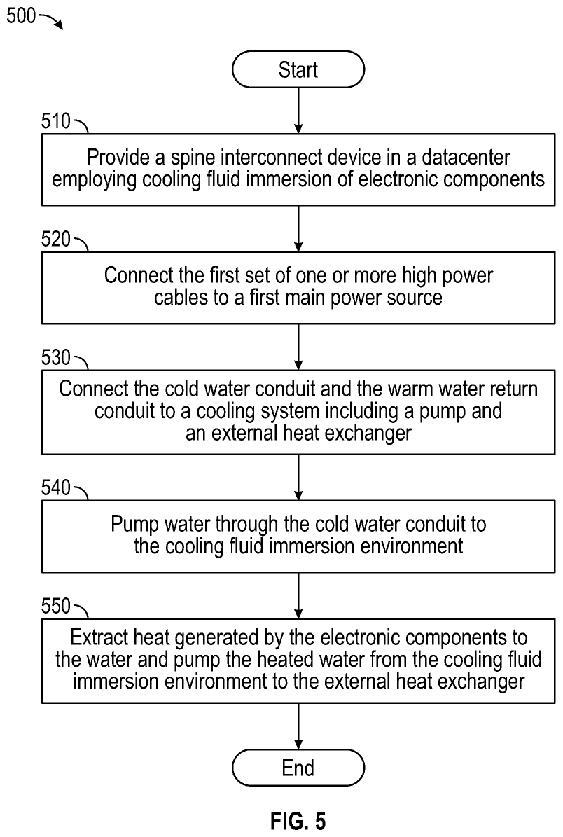

Turning to FIG. 5, FIG. 5 depicts a method 500 for using a spine interconnect device (200) in a datacenter (or to form a datacenter), consistent with one or more embodiments described herein. The steps of FIG. 5 may be performed using a spine interconnect device (200) as discussed above in relation to FIGS. 2 and 3 but are not limited thereto. Furthermore, the steps of FIG. 5 may be performed in any order, such that the steps are not limited to the sequence presented. In addition, multiple steps of FIG. 5 may be performed as a single action, or one step may comprise multiple actions by devices or components described herein.

The method 500 initiates with step 510, where a spine interconnect device is provided in a datacenter employing cooling fluid immersion of electronic components. In accordance with one or more embodiments, the provided spine interconnect device includes a first bus bar containing a first set of one or more high power conductors (e.g., copper) and a first spine support configured to suspend the first bus bar above the electronic components. The provided spine interconnect device further includes a first plurality of tap-off boxes each including a plurality of power ports, where each tap-off box of the first plurality of tap-off boxes is connected to and supported by the first bus bar and connects to one or more of the high power conductors in the first set. The provided spine interconnect device further includes a plurality of power cables interconnecting the plurality of power ports to the electronic components, a cold water conduit and a warm water return conduit disposed at a base of the spine support, and a manifold fluidly connecting the cold water conduit and the warm water return conduit to the cooling fluid immersion environment.

With the spine interconnect device provided in the datacenter, the remaining steps of method 500 are generally directed toward connecting the provided spine interconnect device to at least one main power source and a cooling system such that the power infrastructure and the cooling infrastructure of the datacenter are implemented though the provided spine interconnect device. As such, in step 520 the first set of one or more high power conductors of the spine interconnect device are connected to a first main power source, for example, through a connection box and one or more high power cables interfacing with the first main power source. In some embodiments, the provided spine interconnect device may further include a second bus bar containing a second set of one or more high power conductors. In these instances, step 520 may further include connecting the second set of one or more high power conductors to a second main power source, for example through another connection box and another set of high power cables, where the second main power source can be the same or a different main power source from the first main power source. With the provided spine interconnect device connected to at least one main power source, the provided spine interconnect device may be said to provide power infrastructure to the datacenter.

Continuing with method 500, in step 530 the cold water conduit and the warm water return conduit are connected to a cooling system, where the cooling system includes, for example, a pump and an external heat exchanger or cooling plant. The cooling system dissipates heat captured in the warm water return conduit from the cooling fluid immersion environment to an external environment and resupplies cold water in the cold water conduit. Note that the terms “cold water conduit,” “warm water return conduit,” “water,” and “cold water” are used for concision. In practice, the cooling system can use any suitable coolant, previously described as a second cooling fluid, such as water or water-based coolants such as a mixture of water and ethylene glycol.

In step 540, the second cooling fluid (e.g., water) is pumped through the cold water conduit to the cooling fluid immersion environment such that heat can be transferred from the cooling fluid immersion environment to the second cooling fluid. Finally, in step 550, heat generated by the electronic components is extracted and transferred from the cooling fluid immersion environment to the second cooling fluid (e.g., water) and the second cooling fluid is pumped from the cooling fluid immersion environment to the external heat exchanger. With the provided spine interconnect device connected to the cooling system, and the cooling system made operational through use of its pump and external heat exchanger or cooling plant, the provided spine interconnect device may be said to provide cooling infrastructure to the datacenter.

Although only a few example embodiments have been described in detail above, those skilled in the art will readily appreciate that many modifications are possible in the example embodiments without materially departing from this invention. For example, although the disclosure depicts only straight spine axes, in general, a spine interconnect device may be configured or otherwise arranged with a curved spine axis. Further, while embodiments of the instant disclosure are presented in the context of a datacenter employing a cooling fluid immersion system, the spine interconnect device is not limited to use with cooling fluid immersion systems and can be used with any type of liquid-cooled electronic components. In addition, many modifications will be appreciated by those skilled in the art to adapt a particular instrument, situation, or material to embodiments of the disclosure without departing from the essential scope thereof. Thus, all such modifications are intended to be included within the scope of this disclosure.

Embodiments of the present disclosure may provide at least one of the following advantages. The spine interconnect device provides a single, versatile layout to provide all necessary connectivity (e.g., power, cooling, network) to a wide range of liquid-cooled systems (i.e., those systems with one or more liquid-cooled electronic components). While FIGS. 2 and 4 depict possible embodiments where a cooling fluid immersion system are used, any other container designed to host computing resources and requiring a liquid-cooling loop (e.g., liquid-cooled electronic components) can be used with the spine interconnect device, including heterogeneous combinations of containers. Additionally, the spine interconnect device allows for a stand-alone, compact layout specifically designed for fully liquid-cooled datacenters, where the facility environment does not participate in the cooling of its enclosed systems and/or computing resources. That is, cooling is achieved by direct connection to the cooling loop (i.e., the cold water conduit and the warm water return conduit) on the spine interconnect device. This significantly reduces the cost of developing a datacenter by reducing facility requirements, such as a facility with specific augmentations (e.g., a false floor) or a facility that can provide a minimal level of environment control. Moreover, the spine interconnect device is designed to support extreme power density at scale: the combination of industrial power buses and large capacity cooling loops allow for extreme densities of power delivery and cooling; an order of magnitude larger than most current datacenters can achieve. Further, the spine interconnect device can accommodate significant evolutions of computing systems and cooling containers. For example, the bus bars and cooling loop conduits can be sized to accommodate significant power increases. In such cases, the only parts that may need to be adapted are the tap-off boxes connected to the bus bars and the manifold connected to the cooling loop conduits. In contrast, in a traditional datacenter layout, a significant change in power usage caused by a new generation of processing/storage equipment usually means replacing the power distribution equipment and cooling systems at a significant cost notwithstanding operational disruptions and a large carbon footprint. As evident in the description of the spine interconnect device, the spine interconnect device can be readily constructed using commodity components, with very few specific parts (e.g., spine supports), resulting in significant cost savings and reducing supply chain issues compared to bespoke systems. Finally, the dual bus bar configuration of the spine interconnect device (i.e., the spine interconnect device having a first bus bar and a second bus bar) can supply power from a single main power source (maximum power available, no redundancy) or from two independent main power sources (half power, 2N redundancy).

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

What is claimed is:

1. A spine interconnect device for a datacenter employing a cooling fluid immersion environment of electronic components, the device comprising:
a bus bar support;
a first bus bar suspended from the bus bar support, the first bus bar comprising one or more high power conductors of a plurality of high power conductors;
a second bus bar suspended from the bus bar support, the second bus bar comprising one or more high power conductors of the plurality of high power conductors;
a spine support configured to suspend the bus bar support, the first bus bar, and the second bus bar above the electronic components;
a plurality of tap-off boxes each comprising a plurality of power ports,
wherein each tap-off box of the plurality of tap-off boxes is connected to and supported by the first bus bar or the second bus bar,
wherein each of the plurality of tap-off boxes connects to one or more of the high power conductors;
a plurality of power cables interconnecting the plurality of power ports to the electronic components;
a low power tray supported by the spine support disposed below the first bus bar and the second bus bar and above the electronic components, the low power tray comprising networking cables connected to one or more of the electronic components and a networking switch at a terminal end of the spine interconnect device;
a cold water conduit and a warm water return conduit disposed at a base of the spine support; and
a manifold fluidly connecting the cold water conduit and the warm water return conduit to the cooling fluid immersion environment.

2. The spine interconnect device of claim 1,
wherein the first bus bar receives power from a first main power source and the second bus bar receives power from a second main power source, where the first main power source and the second main power source are independent.

3. The spine interconnect device of claim 1,
wherein the spine support comprises the bus bar support and further comprises an elevation portion, the elevation portion comprising one or more members of adjustable length.

4. The spine interconnect device of claim 3,
wherein a height of the bus bar support relative to a floor on which the spine support is disposed is configured through adjustment of the adjustable length of one or more of the members of the elevation portion.

5. The spine interconnect device of claim 1,
wherein the manifold comprises one or more taps each comprising a valve and an outlet,
wherein the outlet is configured to fasten a hose between the manifold and the cooling fluid immersion environment.

6. The spine interconnect device of claim 1,
wherein the cold water conduit and the warm water return conduit are connected to a cooling system that is not connected to any other spine interconnect device.

7. The spine interconnect device of claim 1,
further comprising another spine support comprising another bus bar support,
wherein an arrangement of the spine support and the another spine support define a spine axis of the spine interconnect device,
wherein the first bus bar, the second bus bar, the low power tray, the cold water conduit, and the warm water conduit are disposed parallel to the spine axis.

8. The spine interconnect device of claim 1,
wherein the spine support comprises one or more floor supports, each floor support configured to be removably attached to a floor on which the spine support is disposed, or
the spine support comprises one or more ceiling supports, each ceiling support configured to suspend the spine support from a ceiling.

9. A method for using a spine interconnect device in a datacenter with a cooling fluid immersion environment of electronic components, the method comprising:
providing the spine interconnect device in the datacenter, the spine interconnect device comprising:
a first bus bar comprising a first set of one or more high power conductors;
a first spine support configured to suspend the first bus bar above the electronic components;
a first plurality of tap-off boxes each comprising a plurality of power ports,
wherein each tap-off box of the first plurality of tap-off boxes is connected to and supported by the first bus bar and connects to one or more of the high power conductors in the first set,
a plurality of power cables interconnecting the plurality of power ports to the electronic components;
a cold water conduit and a warm water return conduit disposed at a base of the spine support; and
a manifold fluidly connecting the cold water conduit and the warm water return conduit to the cooling fluid immersion environment;
connecting the first set of one or more high power conductors to a first main power source;
connecting the cold water conduit and the warm water return conduit to a cooling system comprising a pump and an external heat exchanger;
pumping water through the cold water conduit to the cooling fluid immersion environment; and
extracting heat generated by the electronic components to the water and pumping the heated water from the cooling fluid immersion environment to the external heat exchanger.

10. The method of claim 9,
wherein the spine interconnect device further comprises a second bus bar comprising a second set of one or more high power conductors,
wherein the method further comprises connecting the second set of one or more high power conductors to a second main power source.

11. The method of claim 10, wherein the first main power source and the second main power source are the same.

12. The method of claim 9,
wherein the spine interconnect device further comprises a low power tray supported by the first spine support disposed below the first bus bar and above the electronic components, the low power tray comprising networking cables connected to one or more of the electronic components and a networking switch at a terminal end of the spine interconnect device,
wherein the method further comprises connecting the networking switch to an external system.

13. The method of claim 9,
wherein the spine interconnect device further comprises a second spine support,
wherein the method further comprises suspending the first bus bar from the first spine support and the second spine support.

14. The method of claim 9,
wherein the spine interconnect device further comprises a manifold fluidly connecting the cold water conduit and the warm water return conduit to the cooling fluid immersion environment,
wherein the manifold comprises one or more taps each comprising a valve and an outlet,
wherein the outlet is configured to fasten a hose between the manifold and the cooling fluid immersion environment,
wherein the method further comprises fastening at least a first hose and a second hose between the manifold and the cooling fluid immersion environment, the first hose fluidly connecting to the cold water conduit through the manifold and the second hose fluidly connecting to the warm water return conduit through the manifold.

15. A datacenter, comprising:
a cooling fluid immersion environment of electronic components; and
a first spine interconnect device, comprising:
a first bus bar support;
a first bus bar suspended from the first bus bar support, the first bus bar comprising one or more high power conductors of a first plurality of high power conductors;
a second bus bar suspended from the first bus bar support, the second bus bar comprising one or more high power conductors of the first plurality of high power conductors;
a first spine support configured to suspend the first bus bar support, the first bus bar, and the second bus bar above the electronic components;
a first plurality of tap-off boxes each comprising a plurality of power ports,
wherein each tap-off box of the first plurality of tap-off boxes is connected to and supported by the first bus bar or the second bus bar,
wherein each of the first plurality of tap-off boxes connects to one or more of the high power conductors of the first plurality of high power conductors;
a first plurality of power cables interconnecting the plurality of power ports to the electronic components;
a first low power tray supported by the first spine support disposed below the first bus bar and the second bus bar and above the electronic components, the first low power tray comprising networking cables connected to one or more of the electronic components and a first networking switch at a terminal end of the first spine interconnect device;
a first cold water conduit and a first warm water return conduit disposed at a base of the first spine support; and
a first manifold fluidly connecting the first cold water conduit and the first warm water return conduit to the cooling fluid immersion environment.

16. The datacenter of claim 15, further comprising:
a second spine interconnect device, comprising:
a second bus bar support;
a third bus bar suspended from the second bus bar support, the third bus bar comprising one or more high power conductors of a second plurality of high power conductors;
a fourth bus bar suspended from the second bus bar support, the fourth bus bar comprising one or more high power conductors of the second plurality of high power conductors;
a second spine support configured to suspend the second bus bar support, the third bus bar, and the fourth bus bar above the electronic components;
a second plurality of tap-off boxes each comprising a plurality of power ports,
wherein each tap-off box of the second plurality of tap-off boxes is connected to and supported by the third bus bar or the fourth bus bar,
wherein each of the second plurality of tap-off boxes connects to one or more of the high power conductors of the second plurality of high power conductors;
a second plurality of power cables interconnecting the plurality of power ports to the electronic components;
a second low power tray supported by the second spine support disposed below the third bus bar and the fourth bus bar and above the electronic components, the second low power tray comprising networking cables connected to one or more of the electronic components and a second networking switch at a terminal end of the second spine interconnect device;
a second cold water conduit and a second warm water return conduit disposed at a base of the second spine support; and
a second manifold fluidly connecting the second cold water conduit and the second warm water return conduit to the cooling fluid immersion environment.

17. The datacenter of claim 16,
wherein the first spine interconnect device receives power from a first main power source and the second spine interconnect device receives power from a second main power source, where the first main power source and the second main power source are independent.

18. The datacenter of claim 16,
wherein the first cold water conduit and the first warm water return conduit are connected to a first cooling system,
wherein the second cold water conduit and the second warm water return conduit are connected to a second cooling system.

19. The datacenter of claim 18, wherein the first cooling system and the second cooling system are the same.

20. The datacenter of claim 15,
wherein the first spine interconnect device further comprises a second spine support comprising a second bus bar support,
wherein an arrangement of the first spine support and the second spine support define a spine axis of the first spine interconnect device,
wherein the first bus bar, the second bus bar, the first low power tray, the first cold water conduit, and the first warm water conduit are disposed parallel to the spine axis.
